(19) United States
(12) Patent Application Publication
(10) Pub. No.: US 2025/0331198 A1
(43) Pub. Date: Oct. 23, 2025

(54) MEMORY CHIP STACK HYBRID BONDED TO A PROCESS CHIP

(71) Applicant: International Business Machines Corporation, Armonk, NY (US)

(72) Inventors: Manasa MEDIKONDA, ALBANY, NY (US); Cheng Chi, Jersey City, NJ (US); Tao Li, Slingerlands, NY (US); Ruilong Xie, Niskayuna, NY (US); Joshua M. Rubin, Albanyq, NY (US)

(21) Appl. No.: 18/640,770

(22) Filed: Apr. 19, 2024

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08146; H01L 2224/80895; H01L 2224/80896; H01L 2225/06541; H01L 2225/06589; H01L 2924/1431; H01L 2924/1436

(57) ABSTRACT

A semiconductor device is provided in which a memory chip stack is stacked vertically on, and hybrid bonded to, a process chip. In the semiconductor device, a hybrid bonding interface including dielectric-to-dielectric bonding and metal-to-metal bonding is present between the memory chip stack and the process chip.

### BACKGROUND

The present application relates to semiconductor technology, and more particularly to a semiconductor device including a memory chip stack hybrid bonded to a process chip.

Three dimensional (3D) chip stacking is a technique used to manufacture MOS (metal-oxide semiconductor) integrated circuits (ICs) by stacking a plurality of ICs and interconnecting them vertically using, for instance, through-silicon vias (TSVs) or Cu—Cu connections. This technique allows the ICs to behave as a single device, which can lead to performance improvements at reduced power and smaller footprint than conventional two-dimensional processes.

### SUMMARY

A semiconductor device is provided in which a memory chip stack is stacked vertically on, and hybrid bonded to, a process chip. In the semiconductor device, a hybrid bonding interface including dielectric-to-dielectric bonding and metal-to-metal bonding is present between the memory chip stack and the process chip.

In one aspect of the present application, a semiconductor device is provided. In one embodiment of the present application, the semiconductor device includes a process chip including a process chip frontside back-end-of-the-line (BEOL) interconnect structure located on a first side of a combined front-end-of-the-line (FEOL)/middle-of-the-line (MOL) level, and a process chip backside power distribution network structure located on a second side of the combined FEOL/MOL level. The semiconductor device further includes a memory chip stack including a plurality of memory chips stacked one on top of the other and located above the process chip. In accordance with the present application, each memory chip includes a semiconductor substrate, a combined memory device/MOL level located on the semiconductor substrate, and a memory frontside BEOL interconnect structure located on the combined memory device/MOL level. In accordance with the present application, a hybrid bonding interface is present between the process chip and the memory chip stack.

### BRIEF DESCRIPTION OF THE DRAWINGS

FIG. 1 is a cross sectional view of a process chip wafer that can be employed in accordance with an embodiment of the present application, the process chip wafer includes a first carrier wafer, a first bonding layer, a process chip frontside BEOL interconnect structure, a process chip combined FEOL/MOL level, and a process chip backside power distribution network structure.

FIG. 2 is a cross sectional view of the process chip wafer of FIG. 1 after bonding the process chip backside power distribution network structure to a second carrier wafer utilizing a second bonding layer, and removing the first carrier wafer and the first bonding layer.

FIGS. 3A-3E illustrate a processing flow that can be used to provide a DRAM chip stack in accordance with an embodiment of the present application.

FIG. 4 is a cross sectional view of an alternative DRAM chip stack of the present application.

FIG. 5 is a cross sectional view of an exemplary vertically stacked structure after attaching DRAM chip stacks as shown in FIG. 3E to the process chip wafer as shown in FIG. 2.

FIG. 6 is a cross sectional view of the exemplary vertically stacked structure of FIG. 5 after forming a dielectric layer adjacent to each of the DRAM chip stacks, and forming a fifth carrier wafer on top of the dielectric layer and each of the DRAM chip stacks.

FIG. 7 is a cross sectional view of the exemplary vertically stacked structure of FIG. 6 after removing the second bonding layer and the second carrier wafer to reveal the process chip backside power distribution network structure, and forming solder balls on the physically exposed process chip backside power distribution network structure.

FIG. 8 is a cross sectional of the exemplary vertically stacked structure of FIG. 7 after dicing to provide individual 3D memory chip stack/process chip-containing structures.

FIG. 9 is a cross sectional view of one of the individual 3D memory chip stack/process chip-containing structures after bonding the individual 3D memory chip stack/process chip-containing structure to a packaging substrate, removing the fifth carrier wafer, forming a thermal interface material (TIM) layer, and forming an optional lid.

FIG. 10 is a cross sectional view of another exemplary vertically stacked structure that includes DRAM chip stacks stacked on a process chip wafer and a dielectric layer adjacent to each DRAM chip stack, the process chip wafer includes a process chip semiconductor substrate, a combined FEOL/MOL level and a process chip frontside BEOL interconnect structure, in this embodiment no process chip backside power distribution network structure is initially present.

FIG. 11 is a cross sectional view of the exemplary vertically stacked structure of FIG. 10 after forming a carrier wafer above the dielectric layer and the semiconductor substrate of each DRAM chip stack.

FIG. 12 is a cross sectional view of the exemplary vertically stacked structure of FIG. 11 after flipping the structure, removing the process chip semiconductor substrate wafer and thereafter forming a process chip backside power distribution network structure on a physically exposed backside surface of the combined FEOL/MOL level.

FIG. 13 is a cross sectional view of the exemplary vertically stacked structure of FIG. 12 after forming solder balls on the process chip backside power distribution network structure, and thereafter dicing the vertically stacked structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

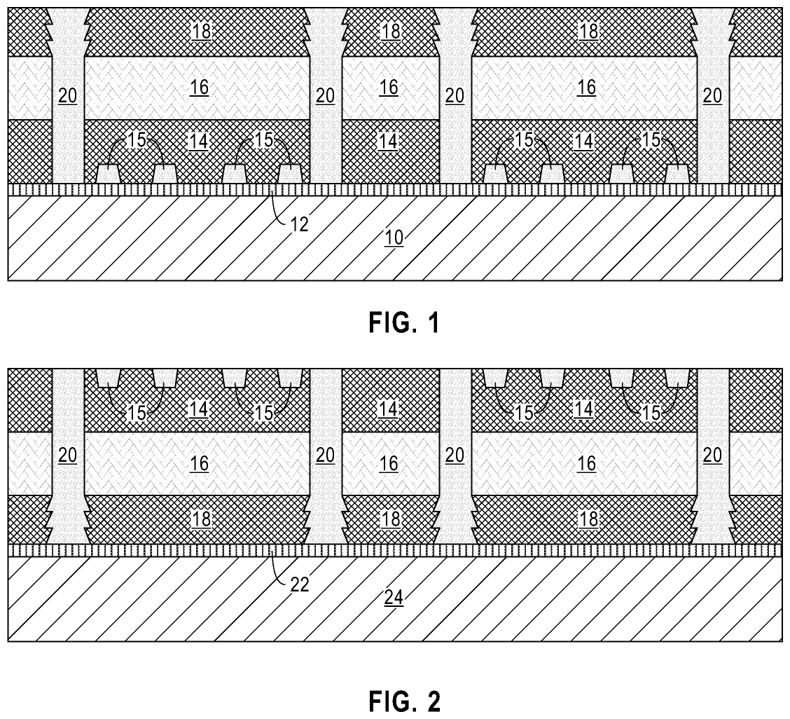

Recently, there has been a growing interest on developing efficient techniques in which memory chips such as a DRAM chip stack can be integrated with a process chip. Process chips have been recently designed to include a backside power distribution network that is located on one side of a combined FEOL/MOL level and a frontside BEOL interconnect structure on the other side of the combined FEOL/MOL level. In the present application, it has been found that integration of a DRAM chip stack with a process chip can be achieved by hybrid bonding The hybrid bonding also allows for a direct electrical connection between the TSVs (or TIVs) and the I/O structures of the DRAM chip stack to the TSVs (or TIVs) and the I/O structures of the process chip. Thus, the present application provides a semiconductor device that enables efficient power transfer through the electrically connected TSVs (or TIVs) of the hybrid bonded DRAM chip stack on the process chip. These and other aspects of the present application will become more apparent by reference to FIGS. 1-13 and the following discussion regarding each of the drawing figures.

Throughout the present application, the term “electrically conductive through structures” is used to denote a structure that is composed of an electrically conductive material (i.e., metal or metal alloy, as further defined below) that passes at least partially, preferably entirely, through either the process chip or the memory chip. The electrically conductive through structure can be TSVs, TIVs, metal lines, metal vias, combined metal lines and metal vias, or any combination of such structures. The electrically conductive through structures can be present on the frontside and/or backside of the process chip and/or memory chip stack.

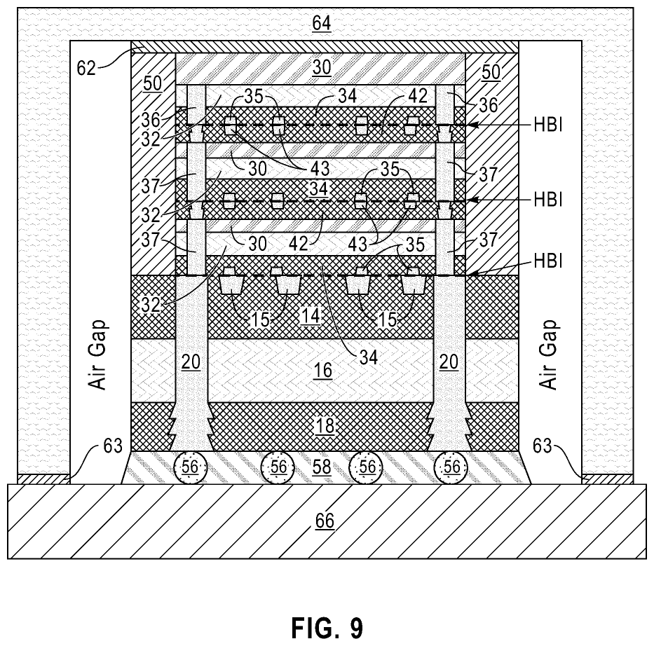

In one embodiment of the present application, a semiconductor device is provided (See, FIG. 9) that includes a process chip including a process chip frontside BEOL interconnect structure 14 located on a first side of a combined FEOL/MOL level 16, and a process chip backside power distribution network structure 18 is located on a second side of the combined FEOL/MOL level 16. The semiconductor device further includes a memory chip stack including a plurality of memory chips stacked one on top of the other and located above the process chip. In accordance with the present application, each memory chip includes a semiconductor substrate 30, a combined memory device/MOL level 32 located on the semiconductor substrate 30, and a memory frontside BEOL interconnect structure 34 located on the combined memory device/MOL level 32. In accordance with the present application, a hybrid bonding interface HBI is present between the process chip and the memory chip stack. In some embodiments, the semiconductor device also includes a packaging substrate 60 attached to the process chip backside power distribution network structure 18. In the present application, the process chip backside power distribution network structure 18 delivers power to the memory chip stack through the process chip electrically conductive through structures 20 and the memory chip electrically conductive through structures 36.

Referring now to FIGS. 1-9, there is illustrated an embodiment of the present application in which a process chip backside power distribution network structure is initially present in the process chip prior to hybrid bonding of a DRAM chip stack to the process chip.

Referring now to FIG. 1, there is illustrated a process chip wafer that can be employed in accordance with an embodiment of the present application. The process chip wafer includes a first carrier wafer 10, a first bonding layer 12, a process chip frontside BEOL interconnect structure 14, a combined FEOL/MOL level 16, and a process chip backside power distribution network structure 18. In the present application, the process chip backside power distribution network structure 18 is located on a first side (i.e., backside) of the combined FEOL/MOL level 16, and the process chip frontside BEOL interconnect structure 14 is located on a second side (i.e., frontside) of the combined FEOL/MOL level 16, which is opposite the first side of the combined FEOL/MOL level 16. Notably, the process chip frontside BEOL interconnect structure 14 is formed on the MOL level of the combined FEOL/MOL level 16. The process chip wafer illustrated in FIG. 1 also includes one or more process chip electrically conductive through structures 20 which extend entirely through the process chip frontside BEOL interconnect structure 14, the combined FEOL/MOL level 16, and the process chip backside power distribution network structure 18. The process chip wafer illustrated in FIG. 1 further includes one or more process chip I/O structures 15 located in the process chip frontside BEOL interconnect structure 14.

The first carrier wafer 10 can be composed of a semiconductor material having semiconductor properties or a dielectric material. Illustrative semiconductor materials that can be used as the first carrier wafer 10 include, but are not limited to, silicon (Si), a silicon germanium (SiGe) alloy, a silicon germanium carbide (SiGeC) alloy, germanium (Ge), III/V compound semiconductors or II/VI compound semiconductors. Illustrative dielectric materials that can be used as the carrier wafer include, for example, a polymer or glass. Typically, the first carrier wafer 10 is composed of Si.

In some embodiments of the present application, the first bonding layer 12 can be composed of a bonding dielectric material such as, for example, tetraethyl orthosilicate (TEOS), silicon dioxide (SiO₂), silicon carbon nitride (SiCN) and/or carbon-doped silicon oxide (SiCOH). In other embodiments of the present application, the first bonding layer 12 can be composed of a laser ablating material such as, for example, a polymer that can withstand the temperature of the bonding process used in the present application, an adhesive material such as, for example, an epoxy, or a film stack that can be employed at high bonding temperatures (400° C. or greater) that includes dielectric materials and metals such as disclosed, for example, in U.S. Pat. No. 11,355,379. Typically, the first bonding layer 12 is composed of SiO₂.

The combined FEOL/MOL level 16 includes a FEOL device level that contains one or more logic devices (such as for, example, logic transistors), and a MOL level that includes frontside contact structures electrically connected to the one or more logic devices and embedded in one or more interlevel dielectric materials. The FEOL device level of the combined FEOL/MOL level 16 can be formed utilizing FEOL processes that are well known to those skilled in the art and includes materials that are also well known to those skilled in the art. The MOL level of the combined FEOL/MOL level 16 can be formed utilizing MOL processes that are well known to those skilled in the art and includes materials that are also well known to those skilled in the art.

The process chip frontside BEOL interconnect structure 14 can include one or more interconnect dielectric material layers that contain frontside metal wires (the metal wires can be composed of any electrically conductive metal or electrically conductive metal alloy) embedded therein. Copper (Cu), aluminum (Al), tungsten (W) or cobalt (Co) are illustrative examples of electrically conductive materials that can be used as the frontside metal wires. In the present application, one or more process chip I/O structures 15 can be present in the process chip frontside BEOL interconnect structure 14. The process chip I/O structures 15 are composed of an electrically conductive metal or electrically conductive metal alloy as mentioned above. The process chip I/O structures 15 will be subsequently bonded to I/O structures that are present in a memory chip stack. For clarity, other I/O structures that can be present on the backside of the process chip wafer are not shown. The process chip frontside BEOL interconnect structure 14 can be formed utilizing processes that are well known to those skilled in the art and includes materials that are also well known to those skilled in the art.

The process chip backside power distribution network structure 18 includes backside interlayer dielectric layers having backside metal wires (the backside metal wires can be composed of any electrically conductive metal or electrically conductive metal alloy) embedded therein. The process chip backside power distribution network structure 18 can be electrically connected to the backside of logic devices that are present in the FEOL device level by at least backside contact structures (not shown).

The process chip electrically conductive through structures 20 are composed of an electrically conductive metal or electrically conductive metal alloy as defined above, and in some embodiments (not shown) a diffusion barrier liner can be present along at least the sidewalls of the electrically conductive metal or electrically conductive metal alloy that provides the process chip electrically conductive through structures 20. The process chip electrically conductive through structures 20 can be formed utilizing processes that are well known to those skilled in the art. In some embodiments, the process chip electrically conductive through structures 20 include a combination of different electrically conductive structures (vias and/or lines) that are present in each of the process chip frontside BEOL interconnect structure 14, the combined FEOL/MOL level 16, and the process chip backside power distribution network structure 18.

The process chip wafer illustrated in FIG. 1 can be formed utilizing processes that are well known to those skilled in the art. For example, the process chip wafer illustrated in FIG. 1 can be formed first forming the FEOL device level including the one or more logic devices, followed by forming the MOL level on the FEOL device level. Next, the process chip frontside BEOL interconnect structure 14 and the process chip I/O structures 15 can be formed on the MOL level, and thereafter the process chip frontside BEOL interconnect structure 14 is bonded to the first carrier wafer 10 utilizing the first bonding layer 12. The process chip electrically conductive through structures 20 can be formed any time after forming the FEOL device level and prior to forming the first bonding layer 12. A portion of the process chip electrically conductive through structures 20 can be formed into each of the FEOL device level, the MOL level and the process chip frontside BEOL interconnect structure 14 after forming the FEOL device level, the MOL level and the process chip frontside BEOL interconnect structure 14. In some embodiments and prior to bonding, the first bonding layer 12 can be formed entirely on the first carrier wafer 10 or entirely on the process chip frontside BEOL interconnect structure 14. In other embodiments and prior to bonding, a first portion of the first bonding layer 12 can be formed on the first carrier wafer 10 and a second portion of the first bonding layer 12 is formed on a portion of the process chip frontside BEOL interconnect structure 14. In some embodiments, the forming of the first bonding layer 12 includes a deposition process such as, for example, chemical vapor deposition (CVD), plasma enhanced chemical vapor deposition (PECVD), atomic layer deposition (ALD), physical vapor deposition or any combination thereof. Bonding typically includes bringing the process chip frontside BEOL interconnect structure 14, with or without, the first bonding layer 12 in intimate contact with the first carrier wafer 10, with or without the first bonding layer 12, and then heating the contacted structures. In some embodiments, the heating step can be omitted. The resultant bonded structure can be flipped to allow backside processing which includes forming the process chip backside power distribution network structure 18 on the backside of the FEOL device level.

Referring now to FIG. 2, there is illustrated the process chip wafer of FIG. 1 after bonding the process chip backside power distribution network structure 18 of the process chip wafer to a second carrier wafer 24 utilizing a second bonding layer 22, and removing the first carrier wafer 10 and the first bonding layer 12. The second carrier wafer 24 includes one of the materials mentioned above for the first carrier wafer 10. The second bonding layer 22 includes one of the materials mentioned above for the first bonding layer 12.

The bonding process used in forming the structure illustrated in FIG. 2 can include the same bonding process used in providing the structure illustrated in FIG. 1. In some embodiments and prior to bonding, the second bonding layer 22 can be formed entirely on the second carrier wafer 24 or entirely on the process chip backside power distribution network structure 18. In other embodiments and prior to bonding, a first portion of the second bonding layer 22 can be formed on the second carrier wafer 24 and a second portion of the second bonding layer 22 can be formed on a portion of the backside power distribution network structure 18. In some embodiments, the forming of the second bonding layer 32 includes a deposition process such as one mentioned above in forming the first bonding layer 12.

The removal of the first carrier wafer 10 and the first bonding layer 12 can include any material removal process (e.g., etching and/or planarization) or debonding process (e.g., laser ablation) known to those skilled in the art. The removal of the first carrier wafer 10 and the first bonding layer 12 physically exposes the surface of the process chip frontside BEOL interconnect structure 14 of the original process chip wafer illustrated in FIG. 1. Also, physically exposed are surfaces of the one or more process chip electrically conductive through structures 20 and one or more process chip I/O structures 15.

In addition to using a process chip wafer as described above, the present application also uses a DRAM chip stack. Although a DRAM chip stack is described and illustrated in the present application, the present application is not limited to DRAM chip stacks, but instead contemplates using other types of memory chip stacks besides or in conjunction with DRAM chip stacks. A DRAM chip stack includes a plurality of DRAM chips that are vertically stacked one on top the other. A DRAM is a type of random-access semiconductor memory that stores each bit of data in a memory cell, usually including a capacitor and a transistor, both typically based on metal-oxide-semiconductor (MOS) technology. In some cases, the DRAM is a two transistor type memory.

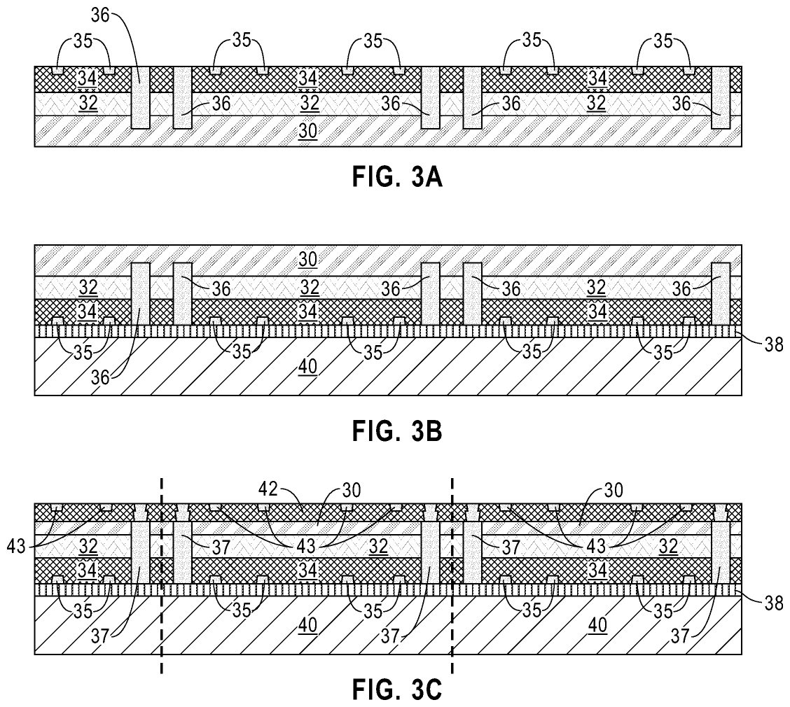

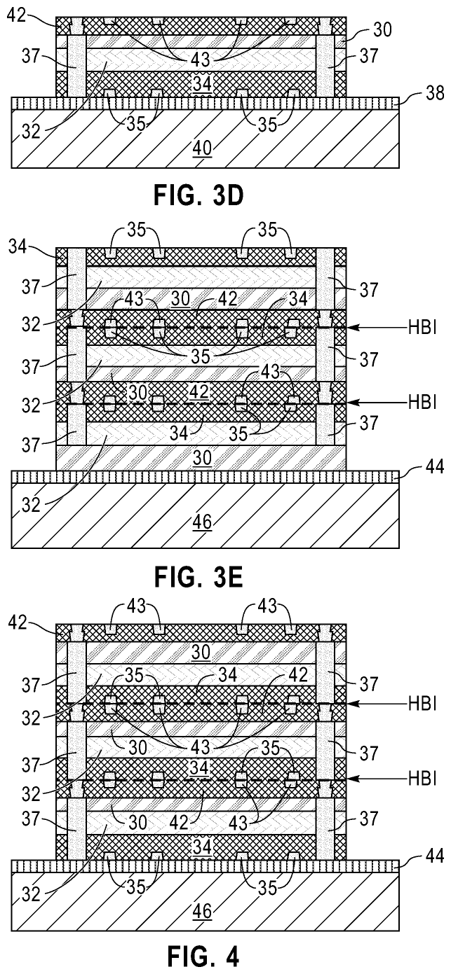

Reference is now made to FIGS. 3A-3E, which illustrate a processing flow that can be used to provide a DRAM chip stack in accordance with an embodiment of the present application. The processing flow begins at the wafer level by providing a DRAM wafer as illustrated in FIG. 3A that includes a semiconductor substrate 30, a combined memory device/MOL level 32 and a frontside DRAM chip BEOL interconnect structure 34. The DRAM wafer illustrated in FIG. 3A can also include DRAM chip I/O structures 35 that are present in the frontside DRAM chip BEOL interconnect structure 34, and precursor DRAM wafer electrically conductive through structures 36 that extend completely through the frontside DRAM chip BEOL interconnect structure 34 and the combined memory device/MOL level 32 and partially into the semiconductor substrate 30.

The semiconductor substrate 30 can include one of the semiconductor materials mentioned above for the first carrier wafer 10. The semiconductor substrate 30 can include an etch stop layer located between a bottommost semiconductor layer and a topmost semiconductor layer. The etch stop layer can be composed of a dielectric material such as, for example, silicon dioxide.

The memory device level of the combined memory device/MOL level 32 includes a memory level including one or more memory (e.g., DRAM) devices and a MOL level that includes frontside contact structures electrically connected to the one or more memory devices and embedded in an interlevel dielectric material. The memory device level of the combined memory device/MOL level 32 can be formed utilizing processes that are well known to those skilled in the art and includes materials that are also well known to those skilled in the art. The MOL level of the combined memory device/MOL level 32 can be formed utilizing processes that are well known to those skilled in the art and includes materials that are also well known to those skilled in the art.

The DRAM frontside BEOL interconnect structure 34, which is positioned on the MOL level of the combined memory device/MOL level 32, can include one or more interconnect dielectric material layers that contain frontside metal wires (the metal wires can be composed of any electrically conductive metal or electrically conductive metal alloy) embedded therein. In the present application, the one or more DRAM chip I/O structures 35 that are located in the DRAM chip frontside BEOL interconnect structure 34 are composed of an electrically conductive metal or electrically conductive metal alloy as defined above. The DRAM chip frontside BEOL interconnect structure 34 and the one or more DRAM chip I/O structures 35 can be formed utilizing processes that are well known to those skilled in the art and includes materials that are also well known to those skilled in the art.

The precursor DRAM wafer electrically conductive through structures 36 are composed of an electrically conductive metal or electrically conductive metal alloy as defined above, and in some embodiments (not shown) a diffusion barrier liner can be present along at least the sidewalls of the electrically conductive metal or electrically conductive metal alloy that provides the precursor DRAM wafer electrically conductive through structures 36. The DRAM chip precursor DRAM wafer electrically conductive through structures 36 can be formed utilizing processes that are well known to those skilled in the art. The precursor DRAM wafer electrically conductive through structures 36 can be formed in segments after forming each of the memory device level of the combined memory device/MOL level 32, the MOL level of the combined memory of the combined memory device/MOL level 32, and the DRAM frontside BEOL interconnect structure 34, or alternatively it can be formed utilizing a single process after the DRAM frontside BEOL interconnect structure 34 is formed.

After providing the DRAM wafer illustrated in FIG. 3A, the DRAM wafer is flipped 180° and the DRAM frontside BEOL interconnect structure 34 is then bonded to a third carrier wafer 40 utilizing a third bonding layer 38 to provide the structure shown in FIG. 3B. The third carrier wafer 40 includes one of the materials mentioned above for the first carrier wafer 10. The third bonding layer 38 includes one of the materials mentioned above for the first bonding layer 12. The bonding used in forming the structure illustrated in FIG. 3B can include the same bonding process used in providing the structure illustrated in FIG. 1. In some embodiments and prior to bonding, the third bonding layer 38 can be formed entirely on the third carrier wafer 40 or entirely on the DRAM frontside BEOL interconnect structure 34. In other embodiments and prior to bonding, a first portion of the third bonding layer 38 can be formed on the third carrier wafer 40 and a second portion of the third bonding layer 38 can be formed on a portion of the DRAM frontside BEOL interconnect structure 34. In some embodiments, the forming of the third bonding layer 38 includes a deposition process such as one mentioned above in forming the first bonding layer 12.

After providing the structure illustrated in FIG. 3B, the semiconductor substrate 30 is thinned to physical expose a surface of the precursor DRAM wafer electrically conductive through structures 36. The thinning of the semiconductor substrate 30 includes a planarization process such as, for example, chemical mechanical planarization (CMP). Next, a DRAM backside power distribution network structure 42 can be formed on a physically exposed surface of the semiconductor substrate 30. Also formed are DRAM backside I/O structures 43 and a DRAM backside electrically conductive through structures (not specifically labeled). The thinning and forming the DRAM backside power distribution network structure 42, DRAM backside I/O structures 43 and the DRAM backside electrically conductive through structures provide the structure shown in FIG. 3C. It is noted that FIG. 3C shows dotted lines to represent the area in which the DRAM wafer will be subsequently diced.

Each DRAM backside electrically conductive through structure is formed through the DRAM backside power distribution network structure 42 and connects to the physically exposed surface of the precursor DRAM wafer electrically conductive through structures 36. Collectively, each combined DRAM backside electrically conductive through structure and precursor DRAM chip electrically conductive through structures 36 provide DRAM chip electrically conductive through structure 37.

The DRAM backside power distribution network structure 42 includes backside interlayer dielectric layers having backside metal wires (the backside metal wires can be composed of any electrically conductive metal or electrically conductive metal alloy) embedded therein. The DRAM backside power distribution network structure 42 can be electrically connected to the backside of memory devices that are present in the memory device level by at least backside contact structures (not shown). The DRAM backside power distribution network structure 42 can be formed utilizing processes that are well known to those skilled in the art.

The DRAM chip I/O structures 35 are composed of an electrically conductive material as defined above for the process chip I/O structure. The DRAM chip I/O structures 35 can be formed utilizing processes that are well known to those skilled in the art.

The DRAM backside electrically conductive through structures are composed of an electrically conductive metal or electrically conductive metal alloy as defined above, and in some embodiments (not shown) a diffusion barrier liner can be present along at least the sidewalls of the electrically conductive metal or electrically conductive metal alloy that provides the DRAM backside electrically conductive through structures. The DRAM backside electrically conductive through structures can be formed utilizing processes that are well known to those skilled in the art. In some embodiments, the DRAM backside electrically conductive through structures include a combination of different electrically conductive structures (vias and/or lines) The DRAM backside electrically conductive through structures can be formed utilizing processes that are well known to those skilled in the art.

Next, a dicing process is performed on the structure illustrated in FIG. 3C to provide a DRAM chip as illustrated in FIG. 3D. The dicing process (i.e., die singulation or wafer dicing) is a process in which DRAM chips are separated from the structure illustrated in FIG. 3D. The dicing process can include scribing and breaking, mechanical sawing (normally with a machine called a dicing saw) or laser cutting. All methods are typically automated to ensure precision and accuracy. Each DRAM chip incudes a portion of the DRAM backside power distribution network structure 42, DRAM chip I/O structures 35, DRAM chip electrically conductive through structures 37, a portion of the semiconductor substrate 30, a portion of the combined memory device/MOL level 32, and a portion of the DRAM frontside BEOL interconnect structure 34.

Next, and as illustrated in FIG. 3E, a DRAM chip stack is provided. For a facedown stacking process as illustrated in FIG. 3E, the bottommost DRAM chip of the DRAM chip stack does not need a DRAM backside power distribution network structure 42. Such a DRAM chip can be processed by dicing the structure shown in FIG. 3B. The DRAM chip stack process begins by bonding the semiconductor substrate 30 of the bottommost DRAM chip of the DRAM chip stack to a fourth carrier wafer 46 utilizing a fourth bonding layer 44. The fourth carrier wafer 46 includes one of the materials mentioned above for the first carrier wafer 10. The fourth bonding layer 44 includes one of the materials mentioned above for the first bonding layer 12. The bonding process can include the same bonding process used in providing the structure illustrated in FIG. 1.

After attaching the bottommost DRAM chip to the fourth carrier wafer 46, the third carrier wafer 40 and the third bonding layer 38 are removed. The removal of the third carrier wafer 40 and the third bonding layer 38 includes a material removal process (e.g., etching and/or planarization) or debonding process (e.g., laser ablation) as mentioned above for removing the first carrier wafer 10 and the first bonding layer.

Further DRAM chip stacking is then performed utilizing DRAM chips as illustrated in FIG. 3E. Notably, the DRAM chip of FIG. 3E is flipped 180° and the DRAM backside power distribution network structure 42 of the flipped DRAM chip is bonded utilizing a hybrid bonding process to the DRAM frontside BEOL interconnect structure 34 of the bottommost DRAM chip such that a hybrid bonding interface HBI is formed. The term “hybrid bonding” denotes dielectric-to-dielectric bonding and metal-to-metal bonding such that a hybrid bonding interface is formed between the bonded dielectric materials and the bonded metals. The term “hybrid bonding interface” denotes an interface containing dielectric-to-dielectric bonding and metal-to-metal bonding. Notably, in the present application, a HBI is formed between the DRAM frontside BEOL interconnect structure 34 and the DRAM backside power distribution network structure 42 of the flipped DRAM chip (dielectric-to-dielectric bonding), the DRAM chip I/O structures 35 the bottommost DRAM chip and the DRAM backside I/O structures 43 of the flipped DRAM chip (metal-to-metal bonding), and the precursor DRAM wafer electrically conductive through structures 36 of the bottommost DRAM chip and the DRAM chip electrically conductive through structures 37 of the flipped DRAM chip (metal-to-metal-bonding).

The hybrid bonding process includes aligning the flipped DRAM chip such that the DRAM backside I/O structures 43 of the flipped DRAM chip are aligned over the DRAM chip I/O structures 35 of the bottommost DRAM chip and the DRAM chip electrically conductive through structures 37 of the flipped DRAM chip are aligned over the precursor DRAM wafer electrically conductive through structures 36 of the bottommost DRAM chip. The aligned DRAM chips are then brought into intimate contact with each other. The bringing the two aligned DRAM chips into intimate contact with each other can include the application of an external force which may or may not remain during the heating step. The heating of the hybrid bonding process includes heating the intimately contacted and aligned DRAM chips from room temperature (i.e., 20° C.-25° C.) up to 450° C.; temperatures greater than 450° C. can also be used in the present application. The heating step is typically performed in an inert ambient such as, for example, He, Ar, Ne or mixtures thereof. The heating steps bonds the two DRAM chips together and provides the hybrid bonding interface HBI between the two DRAM chips. After bonding, the temperature can be lowered back to room temperature. The hybrid bonding process can also include an activation process as described below.

Hybrid bonding refers to a 3D technique to connect semiconductor builds. Hybrid bonding forms connections of semiconductor structures through metal pads which are embedded in a dielectric layer at a bond interface on each semiconductor structure that is being bonded. The dielectric layer at bond interface include, but is not necessarily limited to, TEOS, SiO₂, SiCN, and/or SiCOH. The metal pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them. The dangling bonds and covalent bonding occurs in the present application.

After hybrid bonding, the third carrier wafer 40 and the third bonding layer 38 are then removed (utilizing the same technique mentioned above for removing the third carrier wafer 40 and the third bonding layer 38 from the bottommost DRAM chip) from the flipped DRAM chip that is now hybrid bonded to the bottommost DRAM chip and thereafter additional DRAM chips as illustrated in FIG. 3D are vertically stacked on top of the DRAM chip that is now hybrid bonded to the bottommost DRAM chip utilizing the same processes (i.e., DRAM chip flipping, hybrid bonding and removal of the third carrier wafer 40 and the third bonding layer 38 as described above). In FIG. 3E, a DRAM chip stack is provided that includes three vertically stacked DRAM chips in which a hybrid bonding interface HBI is present between each vertical stacked DRAM chip of the DRAM chip stack that includes hybrid bonding of the components mentioned above. In some embodiments, it is possible to first stack multiple pairs of memory chips and then combine the smaller first stack of memory chips with a large stack; this may have different bonding yields.

Referring now to FIG. 4, there is illustrated an alternative DRAM chip stack of the present application. The alternative DRAM chip stack includes the DRAM chip of FIG. 3D that is attached to the fourth carrier wafer 46 utilizing the fourth bonding layer 44 mentioned above as a bottommost DRAM chip of the DRAM chip stack. In this embodiment, the DRAM backside power distribution network structure 42 of the DRAM chip of FIG. 3D is attached to another wafer carrier (not shown) and thereafter the third carrier wafer 40 and the third bonding layer 38 are removed. The DRAM chip stack is then flipped 180° such that the DRAM frontside BEOL interconnect structure 34 faces the fourth carrier wafer 46. The DRAM chip is then bonded to the fourth carrier wafer 46, and the other carrier wafer (not shown) is thereafter removed. At least one other DRAM chip as illustrated in FIG. 3D is then stacked on top of the bottommost DRAM chip such that the DRAM frontside BEOL interconnect structure 34 faces downward. The stacking includes forming another carrier wafer on the DRAM chip to be stacked, removing the third carrier wafer 40 and the third bonding layer 38, flipping the DRAM chip to be stacked and hybrid bonding the two DRAM chips together such that a hybrid bonding interface forms between each frontside BEOL interconnect structure 34 and DRAM backside power distribution network structure 42 as shown in FIG. 4.

In this embodiment, a hybrid bonding interface HBI is formed between each vertical stacked DRAM chip of the DRAM chip stack. Notably, in this alternative embodiment of present application, a HBI is formed between the DRAM backside power distribution network structure 42 of the lower DRAM chip and the DRAM frontside BEOL interconnect structure 34 of the upper DRAM chip (dielectric-to-dielectric bonding), the DRAM backside I/O structures 43 of the lower DRAM chip and the DRAM chip I/O structures 35 of the upper DRAM chip (metal-to-metal), and the DRAM chip electrically conductive through structures 37 of the lower DRAM chip and the DRAM chip electrically conductive through structures 37 of the upper DRAM chip (metal-to-metal bonding).

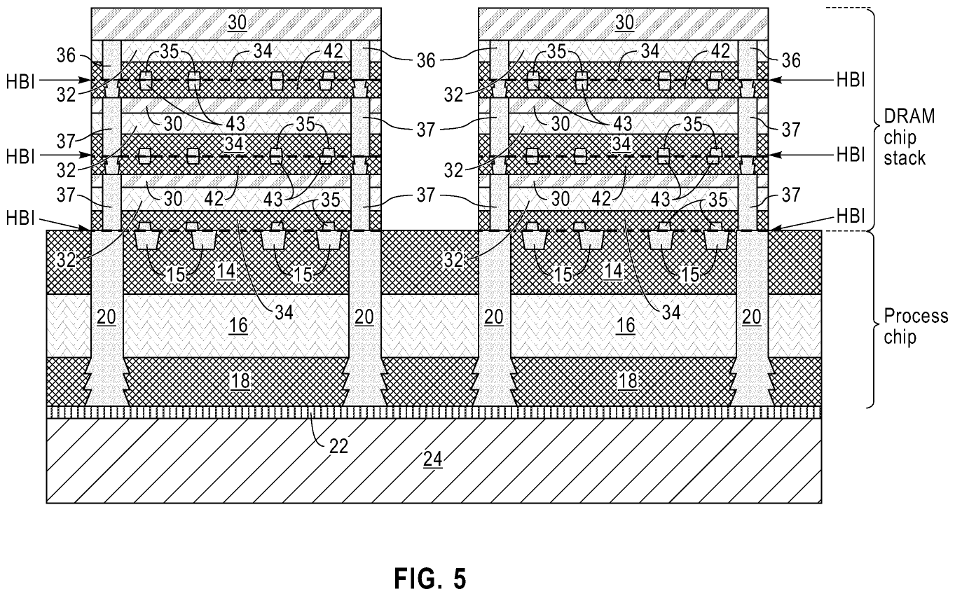

Referring now to FIG. 5, there is illustrated an exemplary vertically stacked structure after attaching DRAM chip stacks as shown in FIG. 3E to the process chip wafer as shown in FIG. 2. Although FIG. 5 uses DRAM chip stacks as illustrated in FIG. 3E, DRAM chip stacks as illustrated in FIG. 4 can be used instead of, or in conjunction with, the DRAM chip stacks illustrated in FIG. 3E. The attaching of the DRAM chip stack as shown in FIG. 3E includes flipping the DRAM chip stack 180° such that the frontside BEOL interconnect structure 34 of the topmost DRAM chip of the DRAM chip stack illustrated in FIG. 3E faces down. The flipped DRAM chip stack is then hybrid bonded (as described above) to one of the process chip frontside BEOL interconnect structures 14 illustrated in FIG. 2. This step is repeated a plurality of times to attached various DRAM chip stacks to the process chip wafer. Hybrid bonding results in a hybrid bonding interface between the frontside BEOL interconnect structure 34 of the flipped DRAM chip stack and the process chip frontside BEOL interconnect structure 14 (dielectric-to-dielectric bonding), DRAM chip I/O structures 35 and the process chip I/O structures 15 (metal-to-metal bonding), and the DRAM chip electrically conductive through structures 37 and the process chip electrically conductive through structures 20 (metal-to-metal bonding). After attaching each of the DRAM chip stacks to the process chip wafer or after each DRAM chip stack is attached to the process chip wafer, the fourth bonding layer 44 and the fourth carrier wafer 42 are removed utilizing techniques as described above in removing the first bonding layer 12 and the first carrier wafer 10. In some embodiments of present application, the semiconductor substrate 30 of the topmost memory chip of the memory chip stack has a thickness that is greater than a thickness of the semiconductor substrate 30 present in the other memory chips that provide the memory chip stack since it is not typically subjected to any thinning step (or if thinning is used it is marginal as compared to the other thinning steps).

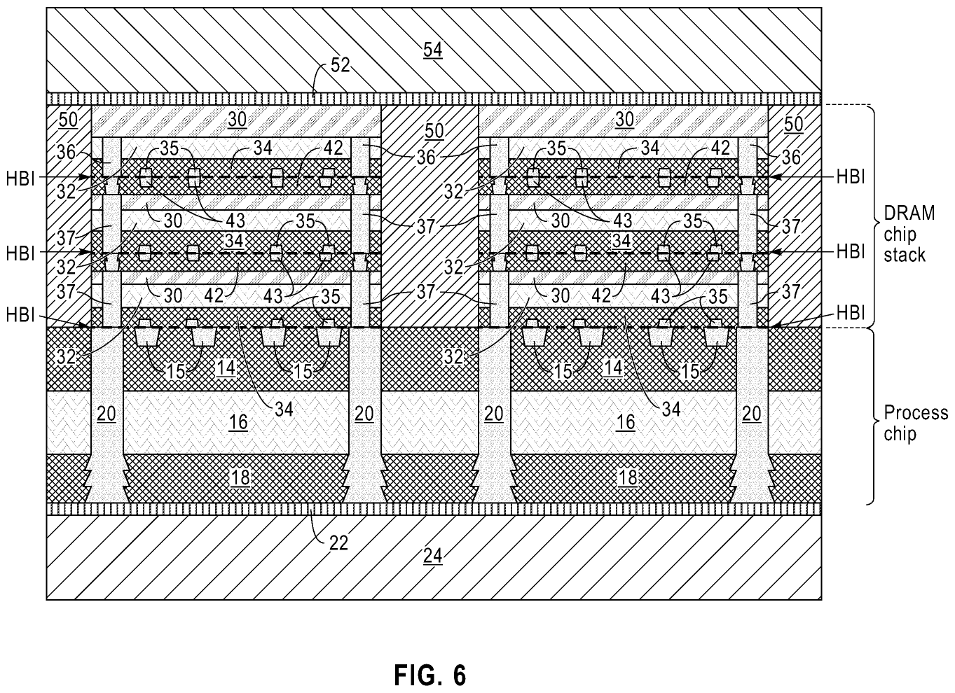

Referring now to FIG. 6, there is illustrated the exemplary vertically stacked structure of FIG. 5 after forming a dielectric layer 50 adjacent to each of the DRAM chip stacks, and forming a fifth carrier wafer 54 on top of the dielectric layer 50 and each of the DRAM chip stacks. The forming of the fifth carrier wafer 54 includes the use of fifth bonding layer 52. The dielectric layer 50 can be composed of any dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 (all dielectric constants mentioned herein are relative to a vacuum unless otherwise noted). Dielectric layer 50 can be formed by a deposition process such as, for example, CVD, PECVD or spin-on coating. A planarization process such as, for example, CMP, can follow the deposition of the dielectric material such that the dielectric layer 50 has a topmost surface that is substantially coplanar with a topmost surface of the physically exposed semiconductor substrate 30 of each of the DRAM chip stacks.

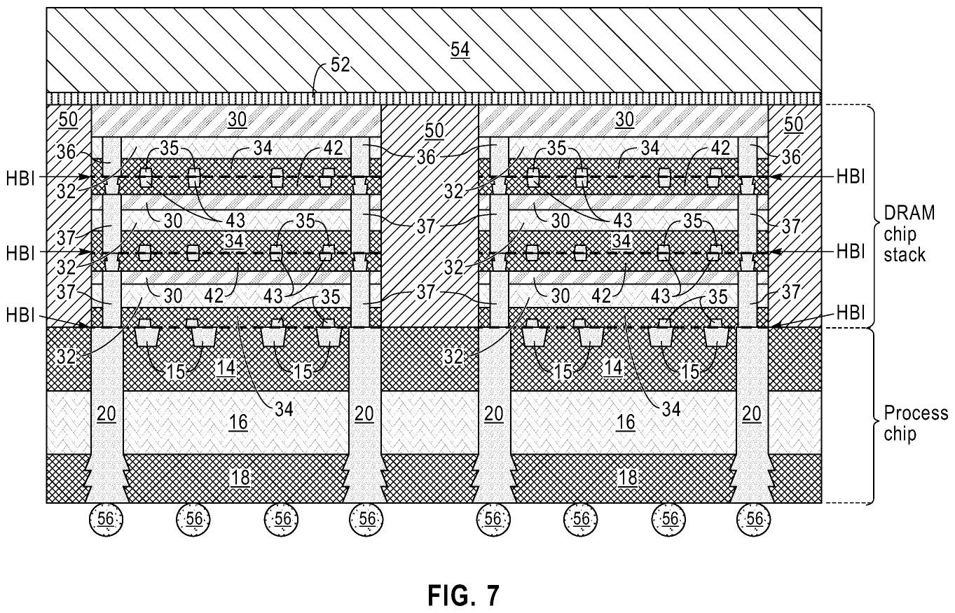

The fifth carrier wafer 54 includes one of the materials mentioned above for the first carrier wafer 10. The fifth bonding layer 52 includes one of the materials mentioned above for the first bonding layer 12. The bonding process used in forming the structure illustrated in FIG. 7 can include the same bonding process used in providing the structure illustrated in FIG. 1.

Referring now to FIG. 7, there is illustrated the exemplary vertically stacked structure of FIG. 6 after removing the second bonding layer 22 and the second carrier wafer 24 to reveal the process chip backside power distribution network structure 18, and forming solder balls 56 on the physically exposed process chip backside power distribution network structure 18; some solder balls 56 can be formed on a physically exposed surface of the process chip electrically conductive through structures 20. The second bonding layer 22 and the second carrier wafer 24 can be removed utilizing the technique mentioned above in removing the first bonding layer 12 and the first carrier wafer 10. The solder balls 56 include any conventional solder ball material such as lead solder balls or lead-free solder balls that are well known to those skilled in the art. The solder balls 56 can be formed utilizing processes that are also well known to those skilled in the art.

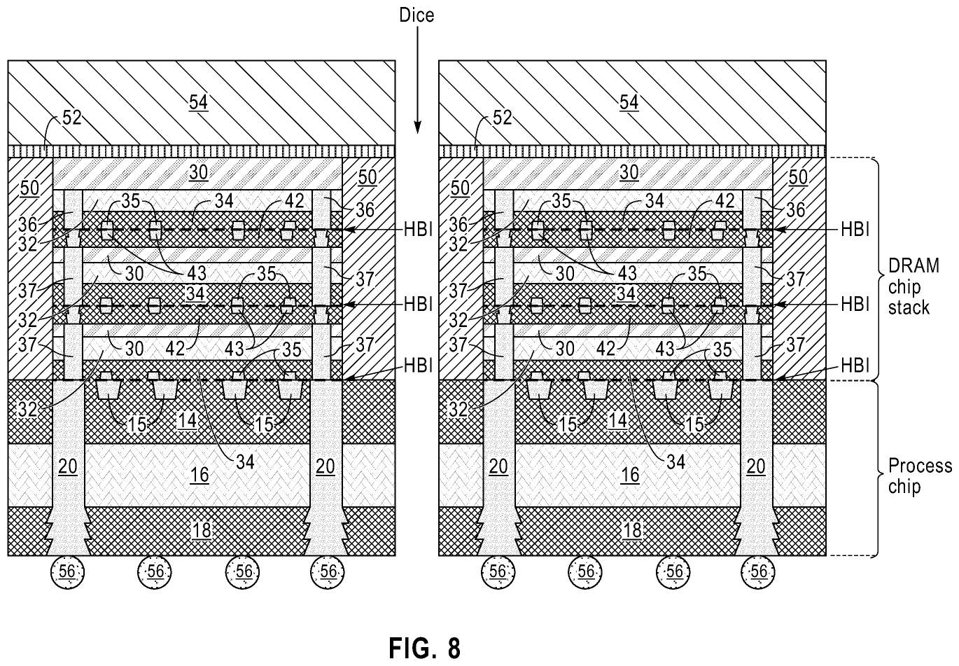

Referring now to FIG. 8, there is illustrated the exemplary vertically stacked structure of FIG. 7 after dicing to provide individual 3D memory chip stack/process chip-containing structures. The dicing used in forming the individual 3D memory chip stack/process chip-containing structures is the same as described above in forming the individual DRAM chip stacks. Each individual 3D memory chip stack/process chip-containing structure includes a process chip and a DRAM chip stack as shown in FIG. 8.

Referring now to FIG. 9, there is illustrated the individual 3D memory chip stack/process chip-containing structures after bonding the individual 3D memory chip stack/process chip-containing structure to a packaging substrate 60, removing the fifth bonding layer 52 and the fifth carrier wafer 54, forming a thermal interface material (TIM) layer 62, and forming an optional lid 64. As is shown, the backside power distribution network structure 18 faces the packaging substrate 60. The packaging substrate 60 includes any conventional package material including an organic laminated substrate that is well known to those skilled in the art. In embodiments of the present application, an underfill material layer 58 can be used to encase each of the solder balls 56 and to fill in any gap that is located between the backside power distribution network structure 18 and the packaging substrate 60. The attaching of the packaging substrate 60 to the solder balls 56 includes contacting the substrate 60 to the solder balls 56, and then applied heat to reflow the solder and form a bond between the solder balls 56 and the packaging substrate 60.

The removal of the fifth carrier wafer 54 and the fifth bonding layer 52 can include any material removal process (e.g., etching and/or planarization) or debonding process (e.g., laser ablation) known to those skilled in the art. After removing the fifth carrier wafer 54 and the fifth bonding layer 52, a TIM layer 62 is formed on the physically exposed surface of the dielectric layer 50 and the physical exposed surface of the semiconductor substrate 30. The TIM layer 62 is composed of materials (e.g., gels, phase change materials and/or greases) that are well known to those skilled int the art. The TIM layer 62 can be formed by a deposition process such as, for example, CVD or PECVD.

When present, the lid 64 can be formed by bonding the lid 64 to the packaging substrate 60 utilizing adhesive 63. Adhesive 63 includes any well known adhesive material. The lid 64 can be composed of a conductive material so as to permit dissipation of heat out of the chip stack. Exemplary conductive materials for the lid 64 include aluminum or copper. In one embodiments no lid is present. In such an embodiment, a heatsink can be present to dissipate heat of the chip stacks; the heatsink can be directly attached to the stacked chips. In some embodiments, an air gap can be present between the lid and the individual 3D memory chip stack/process chip-containing structure that is attached to the packaging substrate 60.

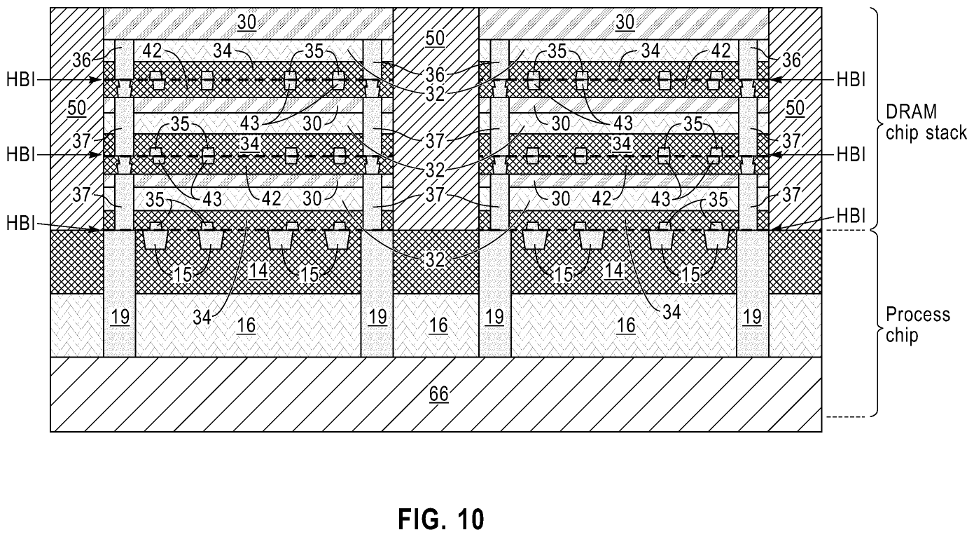

Referring now to FIGS. 10-13, there is illustrated another embodiment of the present application in which a backside power distribution network structure is added to a process chip after hybrid bonding of a DRAM chip stack to the process chip.

Referring first to FIG. 10, there is shown another exemplary vertically stacked structure that includes DRAM chip stack stacked on a process chip wafer and a dielectric layer 50 adjacent to each DRAM chip stack. In this embodiment, the process chip wafer includes a process chip semiconductor substrate 66, a combined FEOL/MOL level 16 and a process chip frontside BEOL interconnect structure 14. In this embodiment, no process chip backside power distribution network structure is initially present. The process chip semiconductor substrate 66 includes a semiconductor material as mentioned above. The combined FEOL/MOL level 16 and the process chip frontside BEOL interconnect structure 14 are as defined above. In this embodiment, the combined FEOL/MOL level 16 is formed on the process chip semiconductor substrate 66 utilizing techniques and materials that are well known to those skilled in the art, and thereafter the process chip frontside BEOL interconnect structure 14 is formed in the combined FEOL/MOL level 16 utilizing techniques and materials that are well known in the art. Note that in this embodiment, the FEOL device level of the combined FEOL/MOL level 16 forms an interface with the process chip semiconductor substrate 66, and the MOL level of the combined FEOL/MOL level 16 forms an interface with the process chip frontside BEOL interconnect structure 14. It is noted that the process chip wafer includes a precursor process chip electrically conductive through structures 19 formed into the combined FEOL/MOL level 16 and the process chip frontside BEOL interconnect structure 14. The precursor process chip electrically conductive through structures 19 include materials mentioned above for the process chip electrically conductive through structures 20, and the precursor process chip electrically conductive through structures 19 can be made utilizing techniques well known to those skilled in the art.

In this embodiment, the DRAM chip stack is the same as that illustrated in FIG. 3E. Notably, each bottommost DRAM chip includes a DRAM frontside BEOL interconnect structure 34 that faces the process chip frontside BEOL interconnect structure 14. In this embodiment, a hybrid bonding interface HBI exists between the DRAM frontside BEOL interconnect structure 34 and the process chip frontside BEOL interconnect structure 14 (dielectric-to-dielectric), the DRAM chip I/O structures 35 and the process chip I/O structure 15 (metal-to-metal bonding) and the DRAM chip electrically conductive through structures 37 and the precursor process chip electrically conductive through structures 19. Although the chip stack illustrated in FIG. 3E is employed, it is possible to use the chip stack that is illustrated in FIG. 4 in this embodiment of the present application.

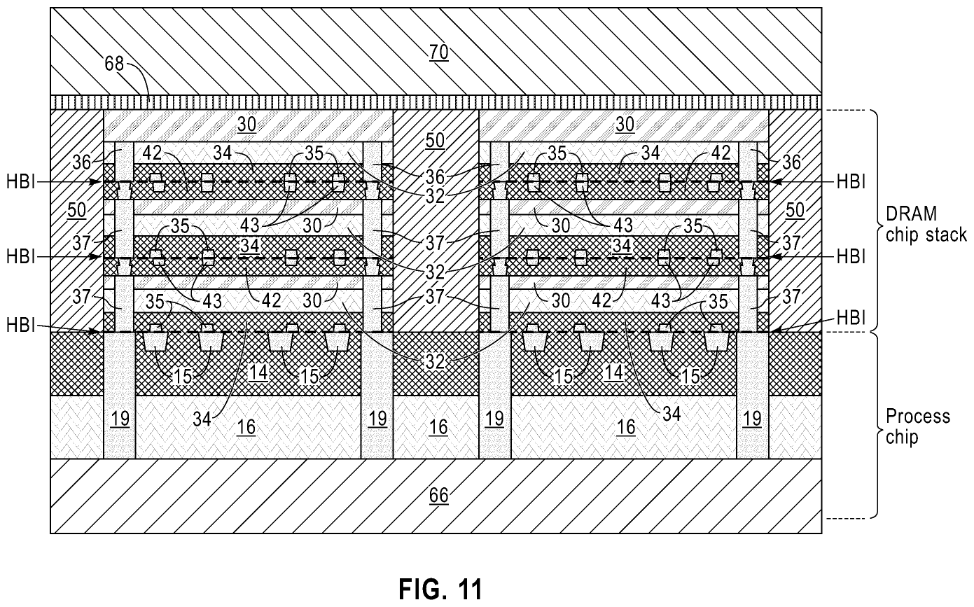

Referring now to FIG. 11, there is illustrated the exemplary vertically stacked structure of FIG. 10 after forming a carrier wafer 70 above the dielectric layer 50 and the semiconductor substrate 30 of each DRAM chip stack. Carrier wafer 70 is attached via a bonding layer 68. Carrier wafer 70 includes one of the materials mentioned above for the first carrier wafer 10. The bonding layer 68 includes one of the materials mentioned above for the first bonding layer 12. The bonding process used in forming the structure illustrated in FIG. 11 can include the same bonding process used in providing the structure illustrated in FIG. 1.

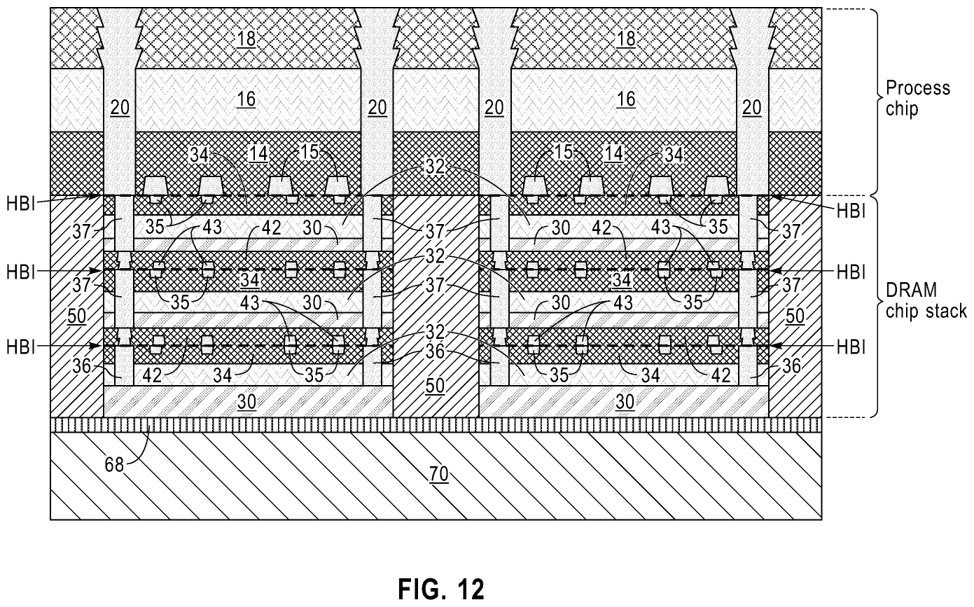

Referring now to FIG. 12, there is illustrated the exemplary vertically stacked structure of FIG. 11 after flipping the structure 180°, removing the process chip semiconductor substrate wafer 66 and thereafter forming a process chip backside power distribution network structure 18 on a physically exposed backside surface of combined FEOL/MOL level 16. After forming the process chip backside power distribution network structure 18 (as defined above), the precursor process chip electrically conductive through structures 19 can be extended into the process chip backside power distribution network structure 18 to provide process chip electrically conductive through structures 20. The extending of the precursor process chip electrically conductive through structures 19 includes a metallization process that is well known to those skilled in the art.

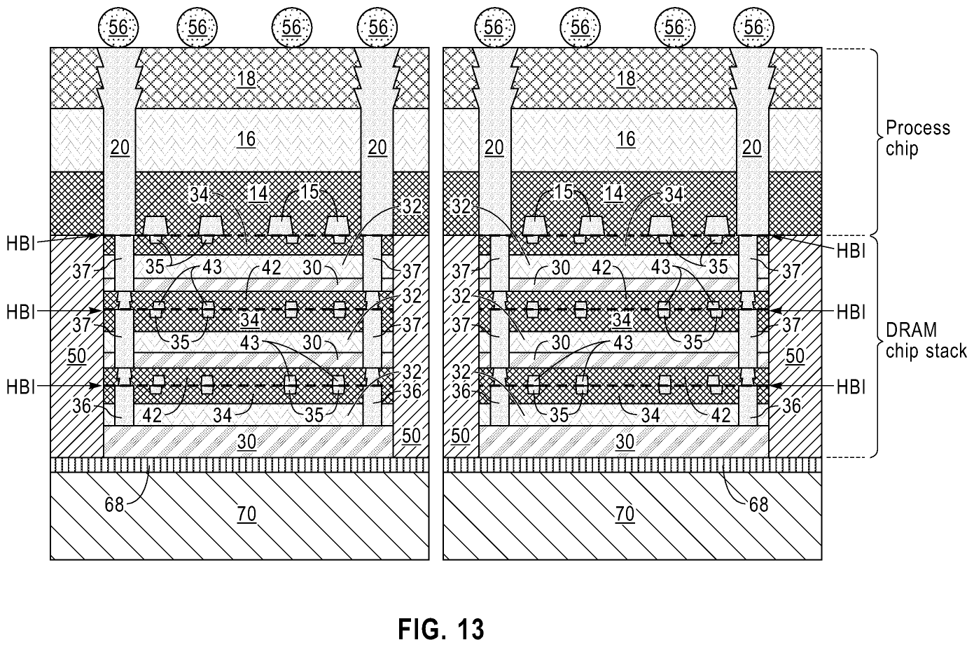

Referring now to FIG. 13, there is illustrated the exemplary vertically stacked structure of FIG. 12 after forming solder balls 56 on the process chip backside power distribution network structure 18, and thereafter dicing the vertically stacked structure. Solder balls 56 are the same as described above. Dicing is also the same as described above. The dicing provides individual 3D memory chip stack/process chip-containing structures which can be processed to include the components shown in FIG. 9. Notably, the processing described above in forming the device shown in FIG. 9 can be applied to the structure illustrated in FIG. 13.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a process chip comprising a process chip frontside back-end-of-the-line (BEOL) interconnect structure located on a first side of a combined front-end-of-the-line (FEOL)/middle-of-the-line (MOL) level, and a power chip backside power distribution network structure located on a second side of the combined FEOL/MOL level; and
a memory chip stack comprising a plurality of memory chips stacked one on top of the other and located above the process chip, wherein each memory chip comprises a semiconductor substrate, a combined memory device/MOL level located on the semiconductor substrate, and a memory frontside BEOL interconnect structure located on the combined memory device/MOL level, wherein a hybrid bonding interface is present between the process chip and the memory chip stack.

2. The semiconductor device of claim 1, wherein the memory frontside BEOL interconnect structure of a bottommost memory chip of the memory chip stack contacts the process chip frontside BEOL interconnect structure at the hybrid bonding interface.

3. The semiconductor device of claim 1, wherein a bottommost memory chip of the memory chip stack includes a memory chip backside power distribution network structure, and the memory chip backside power distribution network structure contacts the process chip frontside BEOL interconnect structure at the hybrid bonding interface.

4. The semiconductor device of claim 1, wherein the memory chip stack comprises at least a chip stack hybrid bonding interface between each of the stacked memory chip stacks.

5. The semiconductor device of claim 1, further comprising a packaging substrate attached to the process chip backside power distribution network structure.

6. The semiconductor device of claim 5, wherein the packaging substrate is attached to the process chip backside power distribution network structure by solder balls.

7. The semiconductor device of claim 6, wherein the solder balls are present in an underfill material layer.

8. The semiconductor device of claim 1, further comprising process chip electrically conductive through structures extending through the process chip.

9. The semiconductor device of claim 8, further comprising memory chip electrically conductive through structures extending through the memory chip stack.

10. The semiconductor device of claim 9, wherein the memory chip electrically conductive through structures are in contact with the process chip electrically conductive through structures at the hybrid bonding interface.

11. The semiconductor device of claim 1, further comprising a thermal interface material layer located on a topmost surface of the memory chip stack.

12. The semiconductor device of claim 1, further comprising a lid contacting a packaging substate, wherein the packaging substrate is attached to the process chip backside power distribution network structure and the lid encloses the process chip and the memory chip stack.

13. The semiconductor device of claim 12, further comprising an adhesive layer located between the lid and the packaging substrate.

14. The semiconductor device of claim 12, further comprising a dielectric layer adjacent to the memory chip stack, and an air gap located between the dielectric layer and the lid.

15. The semiconductor device of claim 1, wherein each memory chip is a dynamic access memory chip.

16. The semiconductor device of claim 1, wherein the combined FEOL/and MOL level of the process chip comprises a FEOL device level including logic devices, and a MOL level located on the FEOL device level.

17. A semiconductor device comprising:
a process chip; and
a memory chip stack located above the process chip, wherein a hybrid bonding interface is present between the process chip and the memory chip stack.
